(19) United States
(12) Patent Application Publication
(10) Pub. No.: US 2007/0288808 A1
(43) Pub. Date: Dec. 13, 2007

(54) Method and system for detecting of errors within optical storage media

(75) Inventors: Jonathan Gulas, Ottawa (CA); Tim Beckwith, Ottawa (CA); Michael Kelland, Ottawa (CA)

Correspondence Address: FREEDMAN & ASSOCIATES, 117 CENTREPOINTE DRIVE, SUITE 350, NEPEAN, ONTARIO, K2G 5X3, CA

(73) Assignee: Clarestow Corporation, Ottawa (CA)

(21) Appl. No.: 11/798,073

(22) Filed: May 10, 2007

Related U.S. Application Data
(60) Provisional application No. 60/799,467, filed on May 10, 2006.

(51) Int. Cl. G11C 29/00

(52) U.S. Cl. 714/718

(57) ABSTRACT

The portability, quality and integrity of optical storage media have made such media the dominant distribution mechanism for a wide variety of audio-visual entertainment including music, films, compilations of television series, and electronic games. The primary distribution being by an initial sale or rental, followed by re-rentals and re-sale. In the later scenarios the integrity or quality of the data stored within the optical storage medium can determine the users overall satisfaction with the audio-visual entertainment, commercial rental organization or commercial re-seller. As such a method of providing a verification or certification of the data within an optical storage medium prior to its return into the distribution chain would be extremely beneficial. According to the invention an optical storage medium is scanned for defects within the data, the determined defects are associated with respective sectors of the optical storage medium, and therein to the content of the data, allowing the impact of the determined defects to be ascertained in respect of the primary audio-visual experience, and ancillary audio-visual experiences provided. Accordingly, the fate of the optical storage media is determined upon this determination, and in some instances its commercial value determined.

This application claims the benefit of U.S. Provisional Application No. 60/799,467, filed on May 10, 2006, the entire contents of which are incorporated herein by reference.

### FIELD OF THE INVENTION

The invention relates to detection of errors within storage media and more particularly to the detection of errors within digital optical media.

### BACKGROUND

With the advent of the gramophone came commercially available recorded music. Commercially available recorded music generated an industry of distribution and sales and soon afterwards an industry of used music sales. Unfortunately, with used music sales the problem of verifying a quality of the used music media arose. As the music media, typically a vinyl disc, was played more and more with a jewel stylus, typically sapphire or diamond, it would become worn down and the quality of the music reproduction would decrease. Similarly, with magnetic tape media repeated use results in a physical stretching of the magnetic media and a reduction of magnetic effects from heat, age etc, these similarly reducing the overall quality of sound reproduction over time. With the advent of video recorders (VCR) the magnetic tape media, such as VHS, were now storing audio-visual content and an entire industry arose aimed at renting entertainment to users.

All of this was supposed to change with the invention of the compact disk (CD), the first commercially viable optically stored digital audio data. The CD provides 80 minutes of recorded music stored in digital audio form according to the international standards. Because the medium is optical, the audio data stored therein is not degraded through playback and, as such, the market for used CDs provides subsequent acquirers with an ability to purchase music with its original quality. With the advent of MP3 as a common digital format a CD can now hold 700 MB of digital audio, allowing over 6 hours of audio to be stored.

Because of this lack of degradation and high reproduction quality achievable with digital media, digital video media followed the CD with the digital video disk (DVD), and is now the ubiquitous distribution method for movies and television shows that are sold, with VHS being phased out by suppliers of audio-visual media. DVDs are also widely rented by consumers from rental organizations such as Blockbuster™. After a film for example has been released for a period of time these rental organizations also sell these DVDs to reduce inventory from the high quantities stocked at initial release, typically 50-100 copies per outlet, to the “library” of films available of only a couple of copies. Further, computer software and video games are now distributed on CDs and DVDs as is music, television shows, and films.

The rental industry aims to ensure that each rental or sales event a satisfying event. In order to achieve this, DVDs are preferably kept in perfect condition. Unfortunately, for the used DVD market and for the DVD rental market it is impossible to force consumers to keep the media in pristine condition. Surface scratches, dirt, and more than substantial damage occur within DVDs and CDs during use by consumers who have little vested interest in the media apart from their single, or limited repeat, use. Though the damage is predictable statistically, the resulting unsatisfactory customer event when the DVD is rented after being damaged is problematic and variable. Generally these events are handled by providing store credits or refunds which do not greatly increases customer satisfaction, and ultimately reduce the operating margin of the renting business.

It would be advantageous to provide a method of evaluating optical storage media upon their return to a rental outlet to determine if they should be returned to inventory and re-rented.

To this end, it has been proposed to read an optical storage medium and to count a number of detected errors. The errors are then reported. Unfortunately, for a typical rental depot employee, the error report does not help them to evaluate a re-rentability of the medium. Also, the error count may have no correlation to the effect of the errors on the experience of the entertainment and, as such, may or may not be a significant measure. Additionally, such errors may occur within the “bonus features” of the audio-visual media and in fact not affect the primary audio-visual content at all.

It would be advantageous to provide a method and system for providing a more accurate indication of the effects of damage on entertainment media based on data within an optical medium.

It would further be advantageous to provide a method and system for providing a method of repairing optical storage media based on an indication of the effects of damage on entertainment based on data within an optical medium.

### SUMMARY OF THE INVENTION

In accordance with the invention there is provided a method for inspecting stored data comprising:
(a) providing an optical storage medium having data stored thereupon, the optical storage medium comprising a plurality of data sectors and having at least an identity;
(b) providing mapping data indicative of a plurality of data sectors of the optical storage medium, the mapping data being indicative of a level of defect sensitivity of each of the plurality of data sectors;
(c) scanning the optical storage medium for detecting defects;
(d) mapping the detected defects to at least a respective data sector of the optical storage medium;
(e) comparing the mapped detected defects with the mapping data of the at least a respective data sector; and,
(f) storing associated with the identity within a computer readable storage medium at least one of the mapped detected defects and the result of the comparison.

In accordance with another embodiment of the invention there is provided a method for certifying stored data comprising:
(a) providing an optical storage medium having data stored therein and comprising a plurality of data sectors, the optical storage medium having at least an identity;
(b) providing first mapping data indicative of a plurality of data sectors of the optical storage medium, the first mapping data indicative of the data content of each of the plurality of data sectors;
(c) providing second mapping data indicative of the plurality of data sectors of the optical storage medium; the second mapping data being indicative of a level of defect sensitivity of each of the plurality of data sectors;
(d) scanning the optical storage medium for detecting defects;
(e) mapping the detected defects to at least a respective data sector of the optical storage medium;
(f) generating a first inspection result, the first inspection result determined by applying a predetermined process to the mapped detected defects, the predetermined process employing at least one of the first mapping data and second mapping data; and
(g) storing associated with the identity within a computer readable storage medium the first inspection result.

In accordance with another embodiment of the invention there is provided a method for certifying stored data comprising:
(a) providing an optical storage medium having data stored therein and comprising a plurality of data sectors, the optical storage having at least an identity;
(b) scanning the optical storage medium at a first scan rate for detecting first defects;
mapping the detected defects to at least a respective data sector of the optical storage medium;
(c) re-scanning data sectors with associated first defects at a second scan rate to detect second defects;
(d) determining first inspection data in dependence upon at least the second defects; and,
(e) storing within a computer readable storage medium at least the first inspection data and an association to the identity.

In accordance with another embodiment of the invention there is provided a method for assessing data comprising:
(a) providing a storage medium having data stored therein relating to an intended user experience, the data having an identity;
(b) extracting the data;
(c) applying at least a known degradation to at least one of the storage medium and a predetermined portion of the data to create baseline data;
(d) providing the baseline data to at least a user of a plurality of users to provide each user with a human experience;
(e) obtaining from each user of the plurality of users at least a user indication of the human experience of the user in respect to the baseline data;
(f) determining a summary indication of human experience from the plurality of user indications of human experience;
(g) storing within a computer readable storage medium at least the summary indication of human experience in association with at least one of the identity of the data, the known degradation, and the predetermined portion of the data degraded.

### BRIEF DESCRIPTION OF THE DRAWINGS

The invention will now be described with reference to the attached drawings in which:

FIG. 1A, shown is a bottom view of an optical medium in the form of a CD;

FIG. 1B is shown a side view of the optical medium;

FIG. 2A, shown is a bottom view of an optical medium in the form of a DVD;

FIG. 2B is shown a side view of the DVD;

FIG. 3 is a simplified flow diagram of a method of reading information from an optical storage medium;

FIG. 4 is a simplified flow diagram of a method of testing an optical storage medium for errors;

FIG. 5 is a simplified flow diagram of a method of testing and repairing an optical storage medium;

FIG. 6 is a simplified flow diagram of a method of determining an effect of detected errors is presented;

FIG. 7 is a simplified flow diagram of a method of determining an effect of detected errors is presented;

FIG. 8 is a simplified flow diagram of a method of determining an effect of detected errors is presented;

FIG. 9 is a simplified flow diagram of a further method according to an embodiment of the invention is shown in simplified flow diagram;

FIG. 10 is a simplified flow diagram of a method of guaranteeing used optical storage media;

FIG. 11 is a simplified flow diagram of a method of certifying optical storage media;

FIG. 12 is a simplified flow diagram of a method of certifying optical storage media; and,

FIG. 13 is a simplified flow diagram of a method for improving error detection efficiency in optical storage media;

### DETAILED DESCRIPTION OF AN EMBODIMENT OF THE INVENTION

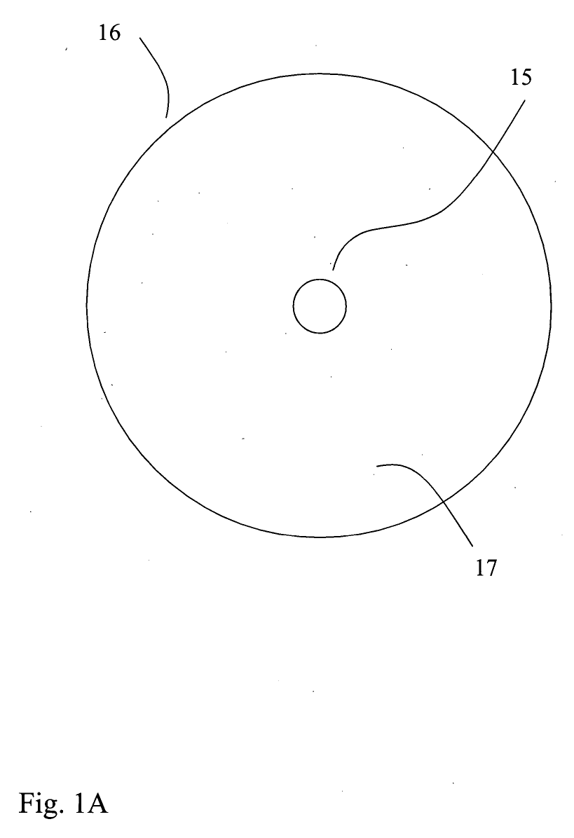

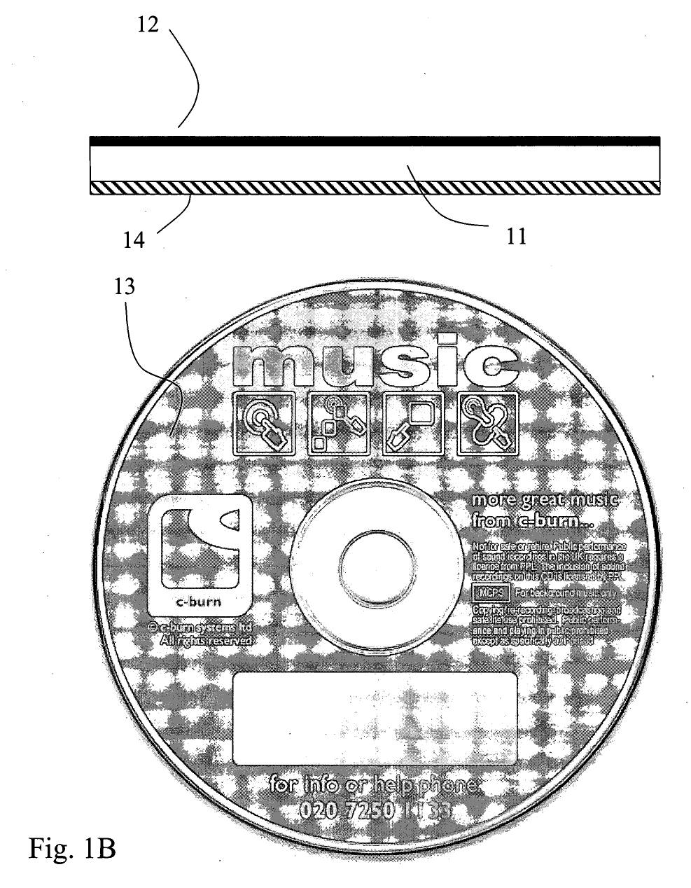

Referring to FIG. 1A, shown is a bottom view of an optical medium in the form of a CD. The optical medium has a hub 15, a rim 16, and an information storage area 17. Within the information storage area 17 bits (binary information) are stored optically. Optical data storage and methods therefore are well known. In FIG. 1B is shown a side view of the optical medium. The optical medium comprises a substrate 11 and an information storage surface 12. Optionally, a label 13 is applied or printed onto an opposing side 14 to the information storage surface 12. Damage to the information storage surface typically results in lost data.

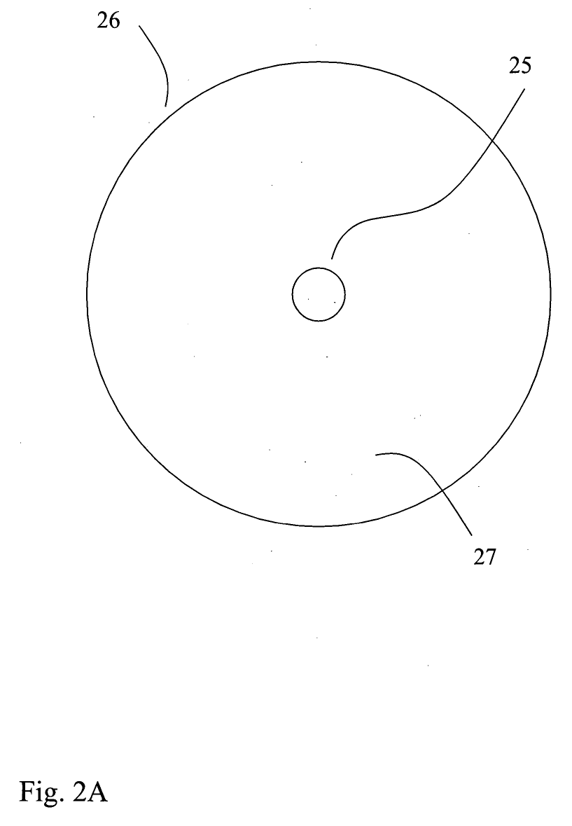

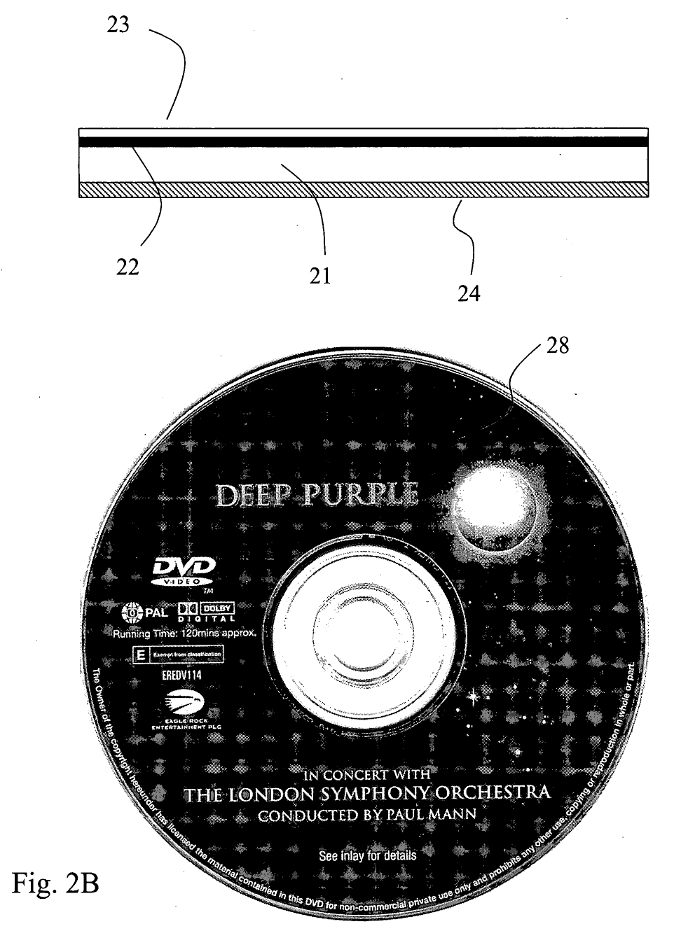

Referring to FIG. 2A, shown is a bottom view of an optical medium in the form of a DVD. The optical medium has a hub 25, a rim 26, and an information storage area 27. Within the information storage area 27 bits (binary information) are stored optically. Optical data storage and methods therefore are well known. In FIG. 2B is shown a side view of the DVD. The DVD comprises a substrate 21, an information storage surface 22, and a protective surface 23. Optionally, a label 28 is applied or printed onto opposite side 24 to the protective surface 23 and information storage surface 24.

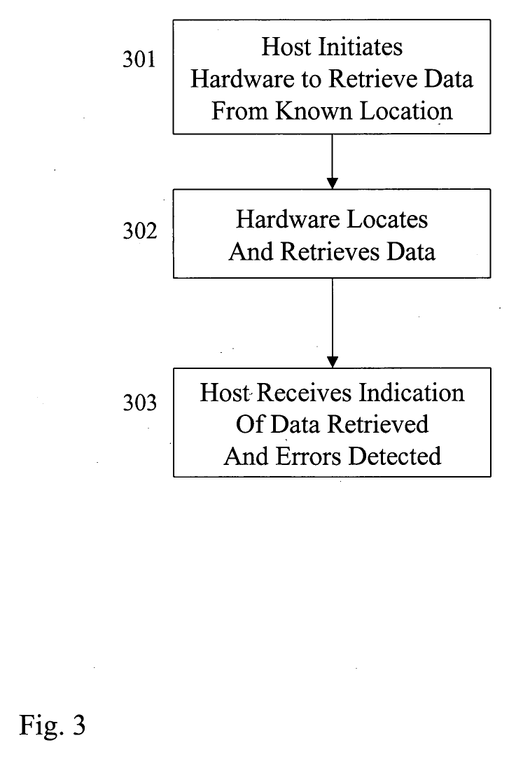

Referring to FIG. 3, shown is a simplified flow diagram of a method of reading information from an optical storage medium. At 301, a command is initiated by a host system for the optical media reading hardware to retrieve data from a known location within the optical storage medium. At 302, the optical media reading hardware locates and retrieves the data from the optical storage medium. As part of the data retrieval process, the optical media reading hardware provides to the host system the data and indication of errors identified, at the hardware level, within the data. These errors typically relate to errors detectable through a use of error detection codes such as checksums, hashes, etc. One of skill in the art of error detection and error correction coding will understand that many different codes are applicable for the recited purpose.

At 303, the host system receives an indication of the data and of errors detected within the data. The host system then proceeds to process the data for use, display, or play depending upon data content. Of course, when data integrity is essential, an indication of an error causes the system to indicate a data read error and cease operation upon the data. Of course, it is well known that for audio and video data, an error does not render the information unusable but sometimes results in errors in display or play of the audio-visual data.

In reading of data from the optical storage medium, the hardware transport reads data at a speed that is an integer multiple of a playback speed for the medium. For example, though a typical CD holds about an hour of music, many presently available optical storage medium readers read data from a complete CD in less than two minutes at speeds of 48 times the playback rate of the music. As such, for data reading the rate is faster and for audio playback the hardware either slows down the reading rate or samples a same bit several times—over sampling—during playback. Over sampling allows for a same bit to be verified through repeated reading.

Unfortunately it is known that for some errors, reading of a single bit at a slower rate is often more accurate than reading of the same bit at a higher rate. That said, it is also known that for reading of data by a computer, faster reading rates are preferred as they allow for faster response times. As such, a cost benefit arises to operating the optical media reading hardware at higher rates—more errors with faster operation and fewer errors with slower operation. This balance is carefully managed in optical storage media optical media reading hardware design.

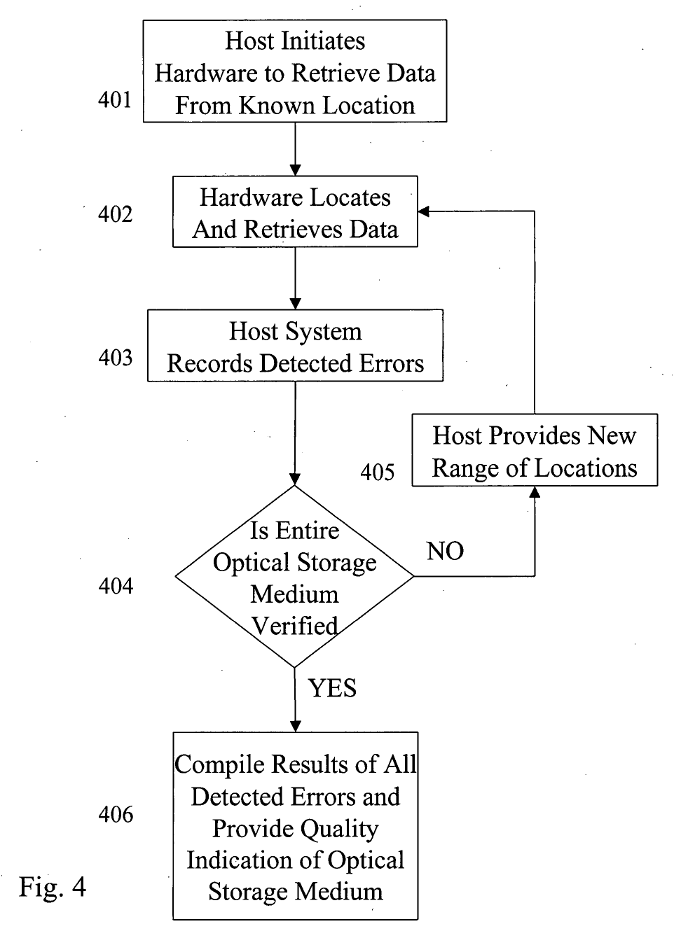

Referring to FIG. 4, shown is a simplified flow diagram of a method of testing an optical storage medium for errors. At 401, a command is initiated by a host system for an optical media reading hardware to retrieve data from a known range of locations within the optical storage medium at a highest available data reading rate. At 402, the optical media reading hardware locates the data and retrieves same from the optical storage medium. As part of the data retrieval process, the optical media reading hardware provides to the host system the data and indication of errors identified, at the hardware level, within the data. These errors typically relate to errors detectable through a use of error detection codes such as checksums, hashes, etc. One of skill in the art of error detection and error correction coding will understand that many different codes are applicable for the recited purpose.

At 403, the host system records any detected errors. At 404 the host system determined whether the entire optical storage medium has been verified. When the storage medium is not yet verified the host system, at 405, provides a command for retrieving data from a new known range of locations within the optical storage medium and then returns to 402. When the entire optical storage medium has been verified, the host system compiles all of the results of detected errors to provide some indication of the quality of the optical storage medium at 406.

Unfortunately, a mere indication of the number of bit errors within data retrieved from an optical storage medium is insufficient to indicate a qualitative effect of the errors. For example on an audio CD, 50 bit errors dispersed throughout the medium and each reflective of a lowest order bit will have little impact on the overall music performance. Alternatively, 50 bit errors within a same block of data will typically have a more significant effect on music playback.

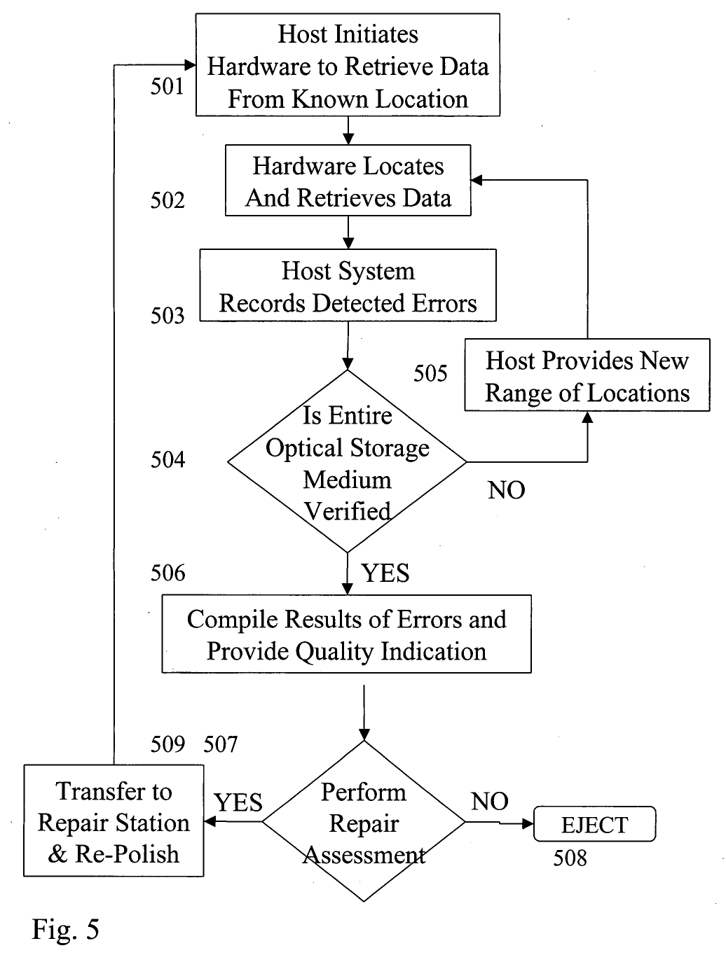

Referring to FIG. 5, shown is a simplified flow diagram of a method of testing and repairing an optical storage medium. At 500, an optical storage medium is cleaned within a cleaning system and transferred to an optical reader. At 501, a command is initiated by a host system for an optical media reading hardware to retrieve data from a known range of locations within the optical storage medium at a highest available data reading rate. At 502, the optical media reading hardware locates the data and retrieves same from the optical storage medium. As part of the data retrieval process, the optical media reading hardware provides to the host system the data and indication of errors identified, at the hardware level, within the data. These errors typically relate to errors detectable through a use of error detection codes such as checksums, hashes, etc. One of skill in the art of error detection and error correction coding will understand that many different codes are applicable for the recited purpose.

At 503, the host system records any detected errors. At 504 the host system determined whether the entire optical storage medium has been verified. When the storage medium is not yet verified the host system, at 505, provides a command for retrieving data from a new known range of locations within the optical storage medium and then returns to 502. When the entire optical storage medium has been verified, the host system compiles all of the results of detected errors to provide some indication of the quality of the optical storage medium at 506.

At 507, an analysis of the detected errors is performed to determine if repair of the optical storage medium is indicated. When repair is not indicated, at 508, the optical storage medium is ejected. When repair is indicated, at 509, the optical storage medium is transferred to a repair system for polishing of the optical storage medium. From the repair system, the optical storage medium is returned to the optical media reading hardware for having data thereon verified and the process returns to 501. This process is iterated until it is determined that the errors are not repairable or that the errors have been repaired.

By automating the repair process, it greatly simplifies the process of optical media verification and repair.

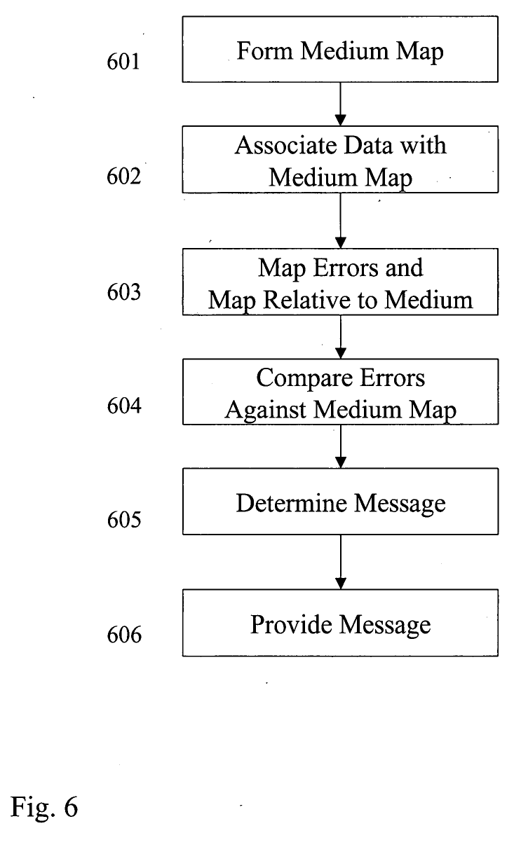

Referring to FIG. 6, a method of determining an effect of detected errors is presented. At 601, a medium map is formed of the optical storage medium in advance relating to an analysis of the data stored therein to determine areas of data that are more sensitive to data errors. At 602, the map is provided with an association to data within the optical storage medium. Here, errors when detected are identified and mapped relative to the storage medium at 603. At 604, the resulting mapped errors are compared against the medium map to determine an effect of the detected errors. For example, some areas within the optical storage medium include data that is critical, other areas include data that is affected by errors but is not critical, and other areas include data that when erroneous only affects some viewers; for example, an area including data relating to Spanish subtitles which only affects those viewing a movie with the subtitles. At 605, comparison results are then used to determine a message to provide in relation to the optical storage medium. Examples of messages include the following: verified; unimportant errors detected; important errors detected; errors detected not for use with . . . , wherein the “ . . . ” represents those who should avoid the medium such as those seeking Spanish subtitles; and errors detected the following will not function, wherein the following lists features such as director's commentary or deleted scenes or alternative audio tracks, and so forth. At 606, the message is provided.

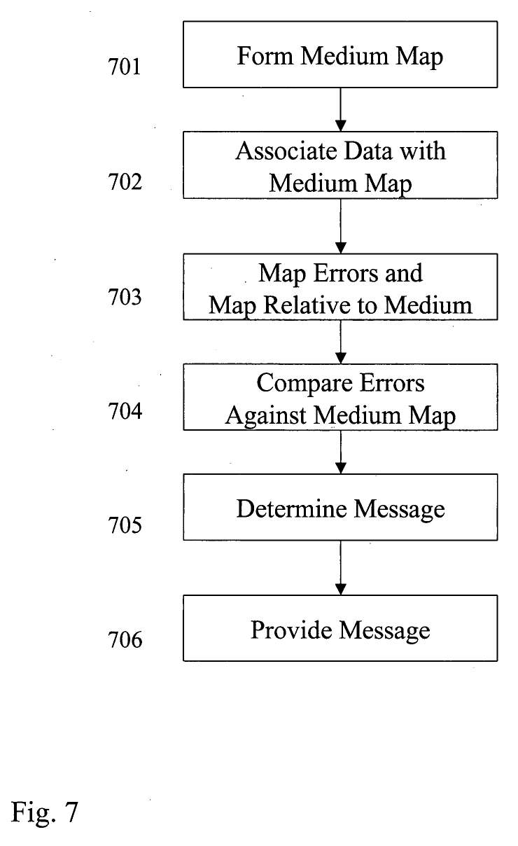

Referring to FIG. 7, a method of determining an effect of detected errors is presented. At 701, a medium map is formed of the optical storage medium in advance relating to an analysis of the data stored therein to determine areas of data and a sensitivity of each area to data errors. At 702, the map is provided with an association to data within the optical storage medium. Here, errors when detected are identified and mapped relative to the storage medium at 703. At 704, the resulting mapped errors are compared against the medium map to determine a likely effect of the detected errors. For example, some areas within the optical storage medium include data that is critical, other areas include data that is less affected by errors, and other areas include data that when erroneous is unlikely to affect a user experience. At 705, comparison results are then used to determine a message to provide in relation to the optical storage medium. Examples of messages include the following: verified; unimportant errors detected; and important errors detected. At 706, the message is provided.

Of course, a combination of the method of FIG. 6 and the method of FIG. 7 is supported wherein criticalness and effect of an error are both considered.

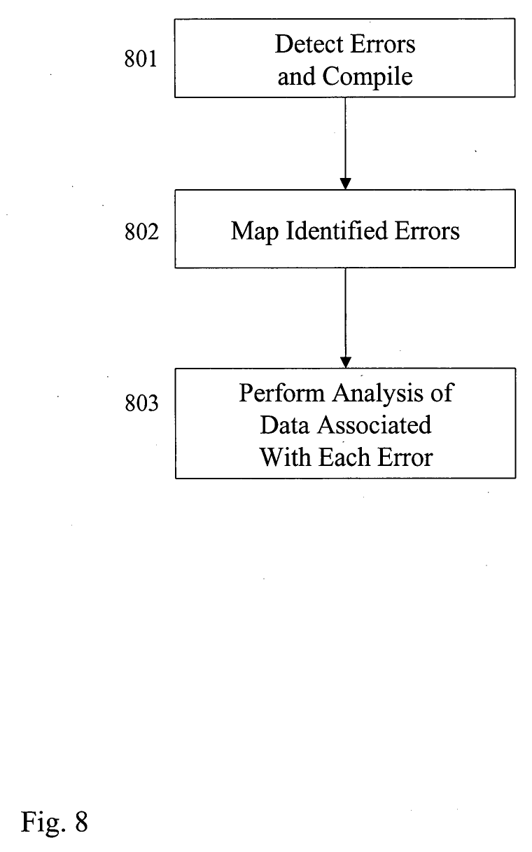

Referring to FIG. 8, a method of determining an effect of detected errors is presented. Here, errors when detected are identified and compiled at 801. The identified errors are then mapped at 802. At 803, for each error, an analysis of the data within the optical storage medium and about the error and within which the error is located is performed. The analysis is for determining for the data a perceptibility of the error when the data is utilized. For example, for a CD a location of the error within a word and number of errors within a same passage of music are evaluated to determine an effect of the errors, either in correlation with predetermined data such as that provided with the embodiments of FIG. 6 and FIG. 7 or through independent analysis against characteristics of the medium content. For example, it is known that with audio data, a lack of harmonicity results in a lower sensitivity to data error. As such, errors within segments of audio data that are inharmonious are less significant than those that occur within highly harmonious segments of audio data. As such, an analysis of audio data determines a likely significance of erroneous data or damage to the optical storage medium. Preferably, detected errors are then reported based on the analysis and the detection of errors to provide data relating to a significance of the errors detected. Similar analysis is possible for video data and for other types of data within the optical storage medium. For example, analysis of focus, clarity and contrast in video images helps to determine an importance of an error, wherein unfocused portions are less susceptible to errors affecting a user experience and more focused portions are more prone to errors being noticeable. Of course, when the analysis is performed in advance a map such as that suggested in the embodiments of FIG. 6 and/or FIG. 7 can be supported. Advantageously, some of the analysis can be done in advance to alleviate processing times for verifying optical media. In combination, analysis is performed as necessary on unrecognized media and on media for which mapping data is unavailable. Further, the process supports improvements to analysis processes and custom analysis processes when used.

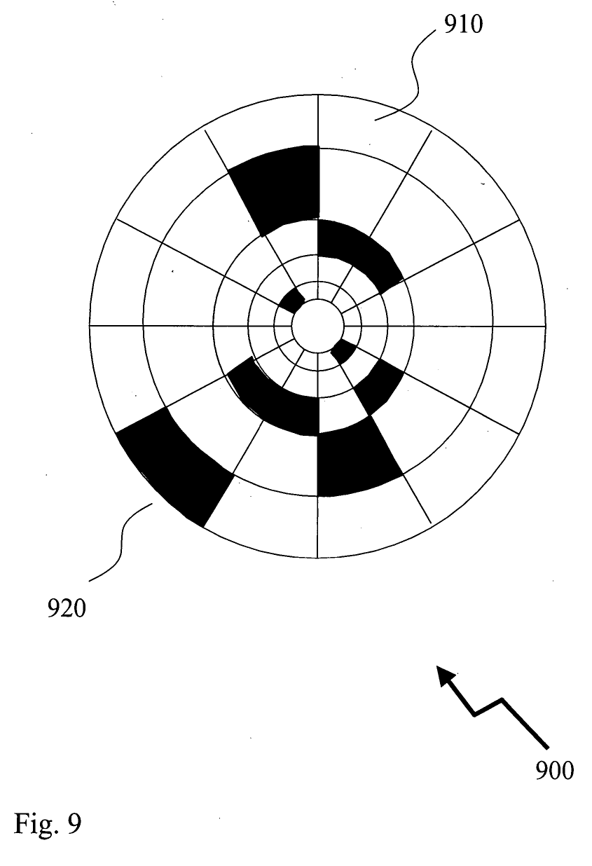

Referring to FIG. 9, a further method according to an embodiment of the invention is shown in simplified flow diagram. Here, a map 900 of essential information is provided for each optical storage medium. The map 900 comprises blocks designated as non-essential blocks 910 and essential blocks 920. Data within any block designated as essential, i.e. essential block 910, must other than have errors therein. For example, for video games, program data blocks are designated as essential information such that errors therein result in a medium being unverifiable. Other data, such as audio data is verified using a more forgiving process as is video data. A result is that data is groupable within optical storage medium for having verification results therefore analyzed differently or according to different standards.

Optionally, the mapping information is provided in association with an identifier associated with a specific optical medium. Alternatively, the process is dependent upon a genre of the optical medium and, as such, analysis of the content is performed based on a predetermined genre specification.

Of course, when previously provided mapping data exists, it is preferable that the mapping data is provided by the media producer. Alternatively, the mapping data is provided by an independent third party. Further alternatively, the mapping data is provided by a user of the verification system or a manufacturer thereof.

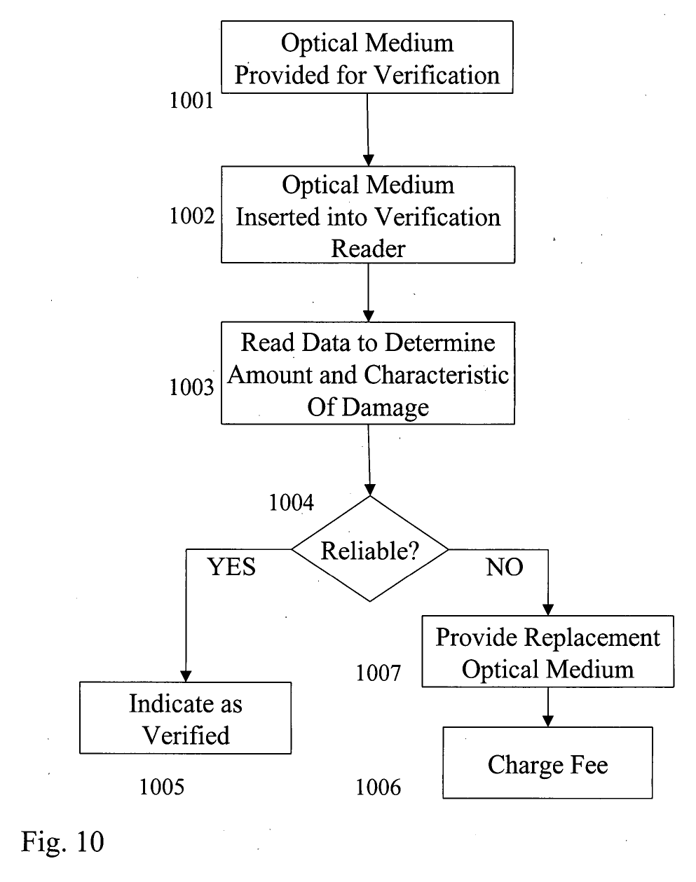

Referring to FIG. 10, shown is a simplified flow diagram of a method of guaranteeing used optical storage media. At 1001, a used optical storage medium is provided for verification. At 1002 the optical storage medium is inserted within an optical medium reader having suitable programming for verifying of optical storage media. The optical medium reader proceeds to read the data from the optical storage medium in order to determine an amount and characteristic of optical storage medium damage at 1003. At 1004, it is determined whether or not the storage medium is sufficiently reliable. When it is, the optical storage medium is indicated as verified at 1005. Alternatively, when it is determined that the storage medium is not verifiable then a new optical storage medium is provided at 1007 and at 1006 a fee is charged for this new optical storage medium. Thus, for example, the provider of the optical storage media generates revenue in replacing of damaged media, the revenue less than the revenue generated for new media. Further alternatively, no fee is charged. Optionally, the unverified optical storage medium is destroyed as part of the replacement process.

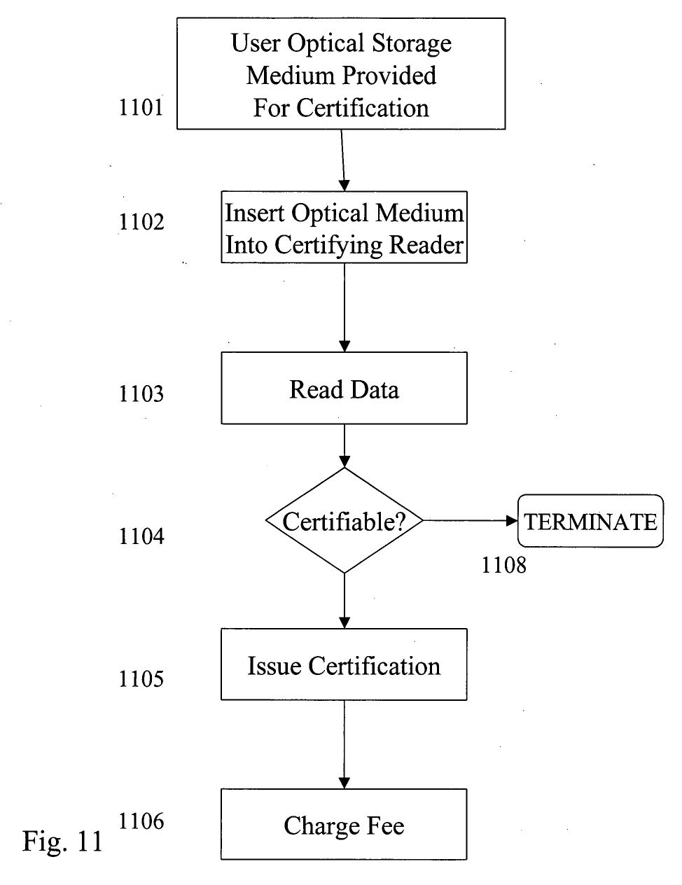

Referring to FIG. 11, shown is a simplified flow diagram of a method of certifying optical storage media. At 1101, a used optical storage medium is provided for certification. At 1102 the optical storage medium is inserted within an optical medium reader having suitable programming for certifying of optical storage media. The optical medium reader proceeds to read the data from the optical storage medium in order to determine an amount and characteristic of optical storage medium damage at 1103. At 1104, it is determined whether or not the storage medium is sufficiently reliable to be certified. When it is, a certification for the optical storage medium is issued at 1105. This is optionally in the form of printing a certification report along with a certification label. Alternatively, it provides a visual indication of certification and a pre-prepared label is then affixed to the medium. At 1106, a fee is charged for the certification. Thus, for example, the provider of the optical storage media generates revenue from the used media market or, alternatively, someone else receives the fee. Further alternatively, no fee is charged. If the storage medium is not sufficiently reliable the process would have been

When the storage medium is not suitable for certification, the certification process fails and the optical storage medium remains uncertified.

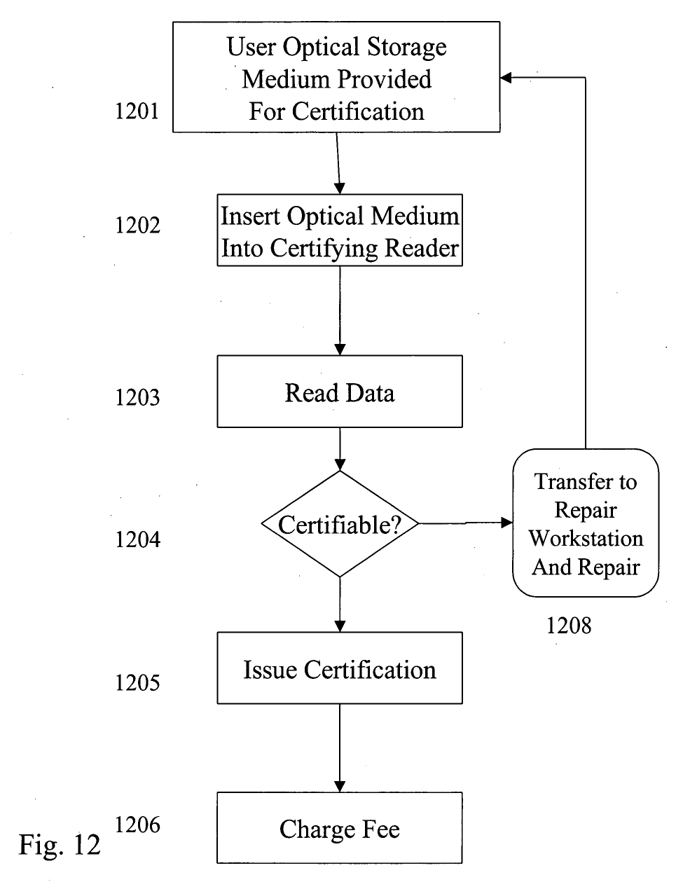

Referring to FIG. 12, shown is a simplified flow diagram of a method of certifying optical storage media. At 1201, a used optical storage medium is provided for certification. At 1202 the optical storage medium is inserted within an optical medium reader having suitable programming for certifying of optical storage media. The optical medium reader proceeds to read the data from the optical storage medium in order to determine an amount and characteristic of optical storage medium damage at 1203. At 1204, it is determined whether or not the storage medium is sufficiently reliable to be certified. When it is, a certification for the optical storage medium is issued at 1205. This is optionally in the form of printing a certification report along with a certification label. Alternatively, it provides a visual indication of certification and a pre-prepared label is then affixed to the medium.

When the storage medium is not suitable for certification, the optical storage medium is provided for repair at 1208 and repair processes undertaken, upon completion of which the optical storage medium is returned to 1201 for certification. Preferably, the failed certification report is provided to the repairing system to facilitate the repair process. Alternatively, the repair system and the certification system are same resulting in an iterative process to try to repair and certify the optical storage medium. With such a system, it is more likely that certification will be successful. At 1206, a fee is charged for the certification. Thus, for example, the provider of the optical storage media generates revenues from the used media market or, alternatively, someone else receives the fee. Further alternatively, no fee is charged.

By charging a fee for certification, an entire new revenue stream is provided that provides to consumers' additional value and to optical storage media producers revenues from a heretofore inaccessible market.

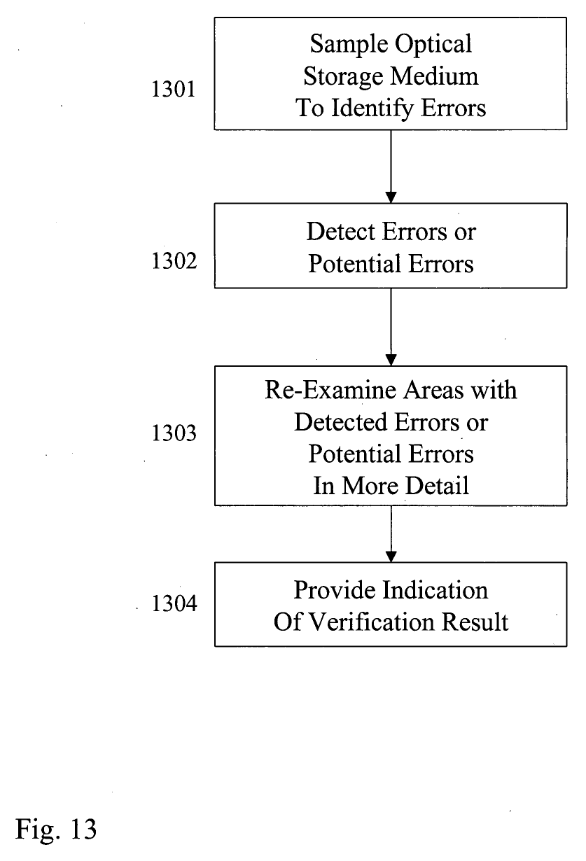

Referring to FIG. 13, shown is a method for improving error detection in optical storage media. Here, an optical storage medium is sampled at 1301 in places to identify potential errors. Individual errors are typically not of significant concern as they are often correctable. What is of concern are areas of error such as those that result from significant damage to an optical medium, dirt on an optical medium, and so forth. When errors are detected at 1302 or potentially detected, the areas with the errors therein are re-examined at 1303 at a slower rate and/or more thoroughly to determine an amount and presence of errors. In this fashion, an entire digital medium is verifiable in a shorter period of time without significant reduction in overall performance. In particular, because of a more thorough review of the optical medium in response to an indication of a potential error or potential errors, it is possible to improve the overall verification of the medium at and about blocks having errors therein. By carefully selecting the sampling frequency and pattern, it is possible to significantly reduce the overall risk that damaged media will go completely undetected when the damage is sufficiently significant to render the media unusable or highly problematic. Once the areas are re-examined, at 1304 an indication of the verification result for the optical medium is provided.

Though the above is described with reference to particular aspects of technology or business, the process of verifying and/or certifying optical storage media is also useful in escrow services. For example, a used optical medium exchange or auction site optionally benefits from a method of ensuring that the optical storage media are viable either before offering for sale or before transferring payment to a vendor. Due to the low cost nature of most optical storage medium on the used market, such a process is preferably fast, automated and inexpensive. Thus, the present method allows for any number of certifying authorities for certifying optical storage media to be conveniently located for providing escrow services. Further, recognized businesses also optionally provide certification of their used optical storage media as a customer service or marketing ploy.

Though the above disclosure relates to optical storage medium readers, the process disclosed is implementable in computer readable instruction data for execution on a computer. Such an implementation is preferably designed to function with multiple optical storage media readers. Preferably, such an implementation is a simple to install and easy to use application.

Alternatively, the methods disclosed herein are applied to multi digital asset management functions such as creating virtual libraries and converting electronic file formats to optical media storage and verifying the quality.

Numerous other embodiments may be envisaged without departing from the spirit or scope of the invention.

What is claimed is:

1. A method for inspecting stored data comprising:
providing an optical storage medium having data stored thereupon, the optical storage medium comprising a plurality of data sectors and having at least an identity;
providing mapping data indicative of a plurality of data sectors of the optical storage medium, the mapping data being indicative of a level of defect sensitivity of each of the plurality of data sectors;
scanning the optical storage medium for detecting defects;
mapping the detected defects to at least a respective data sector of the optical storage medium;
comparing the mapped detected defects with the mapping data of the at least a respective data sector; and,
storing associated with the identity within a computer readable storage medium at least one of the mapped detected defects and the result of the comparison.

2. A method according to claim 1 wherein,
providing mapping data comprises scanning the optical storage medium, extracting content related data, and generating the mapping data in dependence upon the content related data.

3. A method according to claim 1 wherein,
providing mapping data comprises extracting the mapping data from a database, the database storing the mapping data with an association to the identity.

4. A method according to claim 3 wherein,
the mapping data stored within the database is generated by applying a predetermined process to a plurality of human viewing experiences of a plurality of optical storage media with identities matching the identity, each human viewing experience associated with a map of detected defects.

5. A method according to claim 1 further comprising;
generating a first inspection result, the first inspection result determined in dependence upon applying a predetermined process to at least the mapped detected defects.

6. A method according to claim 5 wherein,
generating a first inspection result, the first inspection result determined in dependence upon applying a predetermined process to the mapped detected defects in dependence upon at least the level of defect sensitivity for data sectors with mapped detected defects.

7. A method according to claim 5 further comprising;
providing for at least one scrapping, repairing, pricing, and replacing the optical storage medium when the first certification result meets a predetermined criteria.

8. A method according to claim 7 wherein,
replacing the optical storage medium comprises charging a fee to the owner of the optical storage medium.

9. A method according to claim 7 wherein,
pricing the optical storage medium comprises establishing a target sale price in dependence upon the first inspection result.

10. A method according to claim 5 further comprising;
displaying to a user a message in dependence upon the first certification result, the message comprising at least one of a verification, certificate of quality, a warning, a notification of the errors, a notification of the severity of the errors, and a limitation in the use of the optical storage medium.

11. A method according to claim 6 further comprising;
providing for at least one scrapping, repairing, pricing, and replacing the optical storage medium when the first certification result meets a predetermined criteria.

12. A method according to claim 11 wherein,
replacing the optical storage medium comprises charging a fee to the owner of the optical storage medium.

13. A method according to claim 11 wherein,
pricing the optical storage medium comprises establishing a target sale price in dependence upon the first inspection result.

14. A method according to claim 6 further comprising;
displaying to a user a message in dependence upon the first certification result, the message comprising at least one of a verification, certificate of quality, a warning, a notification of the errors, a notification of the severity of the errors, and a limitation in the use of the optical storage medium.

15. A method for certifying stored data comprising:
(a) providing an optical storage medium having data stored therein and comprising a plurality of data sectors, the optical storage medium having at least an identity;
(b) providing first mapping data indicative of a plurality of data sectors of the optical storage medium, the first mapping data indicative of the data content of each of the plurality of data sectors;
(c) providing second mapping data indicative of the plurality of data sectors of the optical storage medium; the second mapping data being indicative of a level of defect sensitivity of each of the plurality of data sectors;
(d) scanning the optical storage medium for detecting defects;
(e) mapping the detected defects to at least a respective data sector of the optical storage medium;
(f) generating a first inspection result, the first inspection result determined by applying a predetermined process to the mapped detected defects, the predetermined process employing at least one of the first mapping data and second mapping data; and
(g) storing associated with the identity within a computer readable storage medium the first inspection result.

16. A method according to claim 15 wherein,
step (b) comprises scanning the optical storage medium, extracting content related data, and generating the first mapping data in dependence upon the content related data.

17. A method according to claim 15 wherein,
step (b) comprises extracting the first mapping data from a database, the database storing the first mapping data with an association to the identity.

18. A method according to claim 15 wherein,
step (c) comprises extracting the second mapping data from a database storing the second mapping data with an association to the identity.

19. A method according to claim 18 wherein,
step (c) comprises correlating at least one of a plurality of human experiences with data defects within a portion of the plurality of data sectors.

20. A method according to claim 15 further comprising;
(h) providing for at least one scrapping, repairing, pricing, and replacing the optical storage medium when the first inspection result meets a predetermined criteria.

21. A method according to claim 20 wherein,
providing for at least one of comprises replacing the optical storage medium comprises charging a fee to the owner of the optical storage medium.

22. A method according to claim 20 wherein,
providing for at least one of comprises pricing the optical storage medium comprises establishing a target sale price in dependence upon the first inspection result.

23. A method according to claim 20 wherein,
providing for at least one of comprises repairing the optical storage medium comprises performing at least one of a cleaning process and a polishing process to a surface of the optical storage medium and repeating steps (d) through (g).

24. A method according to claim 15 further comprising;
(h) providing a message in dependence upon the first inspection result, the message comprising at least one of a verification, certificate of quality, a warning, a notification of the errors, a notification of the severity of the errors, and a limitation in the use of the optical storage medium.

25. A method for certifying stored data comprising:
(a) providing an optical storage medium having data stored therein and comprising a plurality of data sectors, the optical storage having at least an identity;
(b) scanning the optical storage medium at a first scan rate for detecting first defects; mapping the detected defects to at least a respective data sector of the optical storage medium;
(c) re-scanning data sectors with associated first defects at a second scan rate to detect second defects;
(d) determining first inspection data in dependence upon at least the second defects; and,
(e) storing within a computer readable storage medium at least the first inspection data and an association to the identity.

26. A method according to claim 25 wherein,
step (a) comprises providing first mapping data, the first mapping data indicative of the data content of each of the plurality of data sectors.

27. A method according to claim 26 wherein,
step (c) comprises re-scanning only data sectors with associated first defects within data sectors for which the first mapping data meets a predetermined criteria.

28. A method according to claim 26 wherein,
step (d) comprises providing the first inspection data at least in dependence upon the first mapping data.

29. A method according to claim 25 wherein,
step (a) comprises providing second mapping data indicative of the plurality of data sectors of the optical disk; the second mapping data being indicative of a level of defect sensitivity of each of the plurality of data sectors.

30. A method according to claim 29 wherein,
step (c) comprises re-scanning only data sectors with associated first defects within data sectors for which a result of comparing the first defects with the second mapping data meets a predetermined criteria.

31. A method according to claim 29 wherein,
step (d) comprises providing the first inspection data at least in dependence upon the second mapping data.

32. A method for assessing data comprising:
(a) providing a storage medium having data stored therein relating to an intended user experience, the data having an identity;
(b) extracting the data;
(c) applying at least a known degradation to at least one of the storage medium and a predetermined portion of the data to create baseline data;
(d) providing the baseline data to at least a user of a plurality of users to provide each user with a human experience;
(e) obtaining from each user of the plurality of users at least a user indication of the human experience of the user in respect to the baseline data;
(f) determining a summary indication of human experience from the plurality of user indications of human experience;
(g) storing within a computer readable storage medium at least the summary indication of human experience in association with at least one of the identity of the data, the known degradation, and the predetermined portion of the data degraded.

33. A method for assessing data according to claim 32 further comprising;
(h) providing an optical storage medium having entertainment data stored therein and comprising a plurality of data sectors, the optical storage having at least an identity;
(i) scanning the optical storage medium for detecting defects and mapping the detected defects to at respective portion of the entertainment data;
(j) accessing the computer readable storage medium to determine an anticipated human experience in dependence upon at least the detected defects and respective portions of the entertainment data;
(k) storing within another computer readable storage medium at least the anticipated human experience and an association to the identity.

34. A method according to claim 32 wherein,
step (i) further comprises re-scanning data sectors with associated defects again to detect second defects; and,
step (j) comprises determining the anticipated human experience in dependence upon at least the second detected defects and the respective portions of the entertainment data.

35. A method according to claim 34 wherein,
re-scanning comprises scanning again with at least one of a different scan rate and a different error detection algorithm.

36. A method according to claim 33 further comprising;
(l) providing for at least one scrapping, repairing, pricing, and replacing the optical storage medium in dependence upon the anticipated human experience.
